(19) United States
(12) Patent Application Publication
(10) Pub. No.: US 2020/0244274 A1
(43) Pub. Date: Jul. 30, 2020

(54) INTEGRATED VOLTAGE AND CLOCK REGULATION

(71) Applicant: UNIVERSITY OF WASHINGTON, Seattle, WA (US)

(72) Inventor: Visvesh S. Sathe, Seattle, WA (US)

(21) Appl. No.: 16/261,161

(22) Filed: Jan. 29, 2019

(51) Int. Cl. H03L 7/091; H03K 3/03; H03L 7/089; G06F 1/10; G06F 5/06

(52) U.S. Cl. CPC H03L 7/091; H03K 3/0315; G06F 5/06; G06F 1/10; H03L 7/0891

(57) ABSTRACT

A control circuit includes a digital load, a voltage conversion circuit configured to provide a supply voltage to the digital load, an oscillator configured to provide, to the digital load, a clock signal having an oscillation frequency that (i) depends on the supply voltage and (ii) is less than a reciprocal of a critical path delay of the digital load, and a phase detector configured to provide, to the voltage conversion circuit, a phase signal that is indicative of a phase difference between the clock signal and a reference signal. The voltage conversion circuit is further configured to adjust the supply voltage based on the phase signal such that the oscillator changes the oscillation frequency to reduce the phase difference.

### BACKGROUND

Unless otherwise indicated herein, the materials described in this section are not prior art to the claims in this application and are not admitted to be prior art by inclusion in this section.

Some synchronous digital systems have a first control loop and a second control loop that operates independently from the first control loop. The first control loop can control a supply voltage such that the supply voltage tracks a reference voltage. The supply voltage typically powers a digital load (e.g., a microprocessor). The second control loop controls a clock signal such that a frequency of the clock signal tracks a frequency of a reference clock signal. The clock signal is typically provided to the digital load for timing purposes.

At times, the supply voltage can undesirably drift from the reference voltage. For example, a decreased supply voltage can cause the digital load to require more time to perform a given computation. Meanwhile, the clock signal frequency is typically unaffected by this change in the supply voltage. If the supply voltage decreases enough, timing errors can occur. One way to help prevent such timing errors is to have a built in margin or “guardband” for the supply voltage. However, the built in margin can cause less efficient operation of the digital load.

### SUMMARY

In one example, a control circuit comprises: a digital load; a voltage conversion circuit configured to provide a supply voltage to the digital load; an oscillator configured to provide, to the digital load, a clock signal having an oscillation frequency that (i) depends on the supply voltage and (ii) is less than a reciprocal of a critical path delay of the digital load; and a phase detector configured to provide, to the voltage conversion circuit, a phase signal that is indicative of a phase difference between the clock signal and a reference signal, wherein the voltage conversion circuit is further configured to adjust the supply voltage based on the phase signal such that the oscillator changes the oscillation frequency to reduce the phase difference.

In another example, a method comprises: providing a supply voltage to a digital load; providing, to the digital load, a clock signal having an oscillation frequency that (i) depends on the supply voltage and (ii) is less than a reciprocal of a critical path delay of the digital load; providing a phase signal that is indicative of a phase difference between the clock signal and a reference signal; and adjusting the supply voltage based on the phase signal such that the oscillation frequency changes to reduce the phase difference.

When the term “substantially” or “about” is used herein, it is meant that the recited characteristic, parameter, or value need not be achieved exactly, but that deviations or variations, including, for example, tolerances, measurement error, measurement accuracy limitations, and other factors known to those of skill in the art may occur in amounts that do not preclude the effect the characteristic was intended to provide. In some examples disclosed herein, “substantially” or “about” means within +/−0-5% of the recited value.

The following publications are hereby incorporated by reference into the present disclosure: (1) Rahman, Fahim & Kim, Sung & John, Naveen & Kumar, Roshan & Li, Xi & Pamula, Venkata Rajesh & A. Bowman, Keith & S. Sathe, Visvesh, “An All-Digital Unified Clock Frequency and Switched-Capacitor Voltage Regulator for Variation Tolerance in a Sub-Threshold ARM Cortex M0 Processor,” 2018 IEEE Symposium on VLSI Circuits, (2) Xun Sun, Sung Kim, Fahim ur Rahman, Venkata Rajesh Pamula, Xi Li, Naveen John, Visvesh S. Sathe, “A combined all-digital PLL-buck slack regulation system with autonomous CCM/DCM transition control and 82% average voltage-margin reduction in a 0.6-to-1.0V cortex-M0 processor,” 2018 IEEE International Solid-State Circuits Conference—(ISSCC), and (3) Samantak Gangopadhyay, Saad B. Nasir, A. Subramanian, Visvesh Sathe, Arijit Raychowdhury, “UVFR: A Unified Voltage and Frequency Regulator with 500 MHz/0.84V to 100 KHz/0.27V operating range, 99.4% current efficiency and 27% supply guardband reduction,” ESSCIRC Conference 2016: 42nd European Solid-State Circuits Conference.

These, as well as other aspects, advantages, and alternatives will become apparent to those of ordinary skill in the art by reading the following detailed description, with reference where appropriate to the accompanying drawings. Further, it should be understood that this summary and other descriptions and figures provided herein are intended to illustrate the invention by way of example only and, as such, that numerous variations are possible.

### BRIEF DESCRIPTION OF THE DRAWINGS

FIG. 1 is a schematic diagram of a control circuit, according to an example embodiment.

FIG. 2 is a block diagram of a method, according to an example embodiment.

FIG. 3 illustrates a supply voltage droop and control circuit responses, according to an example embodiment.

FIG. 4 illustrates a supply voltage spike and control circuit responses, according to an example embodiment.

### DETAILED DESCRIPTION

As discussed above, improved circuits and methods for regulating a clock signal and a voltage supply are needed. Such circuits and methods are discussed in the present disclosure.

Within examples, a control circuit includes a digital load (e.g., a microprocessor), a voltage conversion circuit, an oscillator (e.g., a voltage controlled oscillator or “VCO”), and a phase detector. The voltage conversion circuit provides a (e.g., nominally constant) supply voltage to the digital load. The oscillator provides, to the digital load, a clock signal (e.g., a square wave) having an oscillation frequency that (i) is (e.g., monotonically) dependent on the supply voltage and (ii) is less than a reciprocal of a critical path delay of the digital load. The phase detector provides, to the voltage conversion circuit, a phase signal that is indicative of a phase difference between the clock signal and a reference signal. The voltage conversion circuit also adjusts the supply voltage based on the phase signal such that the oscillator changes the oscillation frequency to reduce the phase difference.

For example, an increase in current drawn by the digital load can cause the supply voltage to decrease or “droop.” The decrease in the supply voltage generally increases the time required for the digital load to perform computations (e.g., for inputs to be propagated through combinational or sequential logic paths of the digital load to be manifested as outputs). That is, the critical path delay of the digital load increases. This decreases the clock frequency at which the digital load could conceivably operate without timing errors. The oscillator can receive the supply voltage and, in response to the decrease in the supply voltage, decrease the oscillation frequency of the clock signal. This can beneficially prevent the increased critical path delay of the digital load from causing timing errors. That is, the oscillator can operate to prevent the clock signal from “getting ahead” of the operations of the digital load.

Next, the phase detector can receive the clock signal and provide, to the voltage conversion circuit, a phase signal that is indicative of a phase difference between the clock signal and a reference signal. Referring to the example above, the phase detector receives the clock signal, compares the clock signal to a reference clock, and provides a phase signal that indicates the degree to which the clock signal lags behind the reference clock. In this context, the reference clock is a signal having a constant oscillation frequency that does not change substantially over time.

The voltage conversion circuit can receive the phase signal and, based on the indicated lag of the clock signal with respect to the reference clock, can increase the supply voltage so that the oscillation frequency of the clock signal not only increases to be substantially equal to the oscillation frequency of the reference clock, but also so that the oscillation frequency of the clock signal increases to be greater than the oscillation frequency of the reference clock for a duration necessary to substantially eliminate the phase difference between the clock signal and the reference clock. That is, the voltage conversion circuit adjusts (e.g., increases) the supply voltage such that the clock signal “catches up” with the reference signal.

In a related example, a decrease in current drawn by the digital load can cause the supply voltage to increase or “spike.” The increase in the supply voltage generally decreases the time required for the digital load to perform computations (e.g., for inputs to be propagated through combinational or sequential logic paths of the digital load to be manifested as outputs). That is, the critical path delay of the digital load decreases. This increases the clock frequency at which the digital load could conceivably operate without timing errors. The oscillator can receive the supply voltage and, in response to the increase in the supply voltage, increase the oscillation frequency of the clock signal. This can beneficially reduce the difference between the critical path delay of the digital load and the period of the clock signal, improving timing efficiency.

Referring to the example above, the phase detector receives the clock signal, compares the clock signal to a reference clock, and provides a phase signal that indicates the degree to which the clock signal leads the reference clock.

The voltage conversion circuit can receive the phase signal and, based on the indicated lag of the reference clock with respect to the clock signal, can decrease the supply voltage so that the oscillation frequency of the clock signal not only decreases to be substantially equal to the oscillation frequency of the reference clock, but also so that the oscillation frequency of the clock signal decreases to be less than the oscillation frequency of the reference clock for a duration necessary to substantially eliminate the phase difference between the clock signal and the reference clock. That is, the voltage conversion circuit adjusts (e.g., decreases) the supply voltage such that the reference signal “catches up” with the clock signal.

As such, the control circuit can operate to account for transient deviations in operating conditions of the digital load as noted above, but after the transient deviations are addressed, the control circuit generally controls the supply voltage to control the oscillation frequency of the clock signal to match a predetermined frequency (e.g., f=2 GHz) during steady state conditions. One potential advantage of the control circuit is that it can control the clock signal to achieve not only frequency lock but true phase lock with the reference signal.

Changes in ambient temperature of the digital load will also affect the operation of the control circuit. For example, increased temperature will generally cause the critical path delay of the digital load to increase. In response, the control circuit will generally decrease the oscillation frequency of the clock signal so that the clock signal does not get ahead of the operation of the digital load and cause timing errors. Decreased temperature will generally cause the critical path delay of the digital load to decrease. In response, the control circuit will generally increase the oscillation frequency of the clock signal.

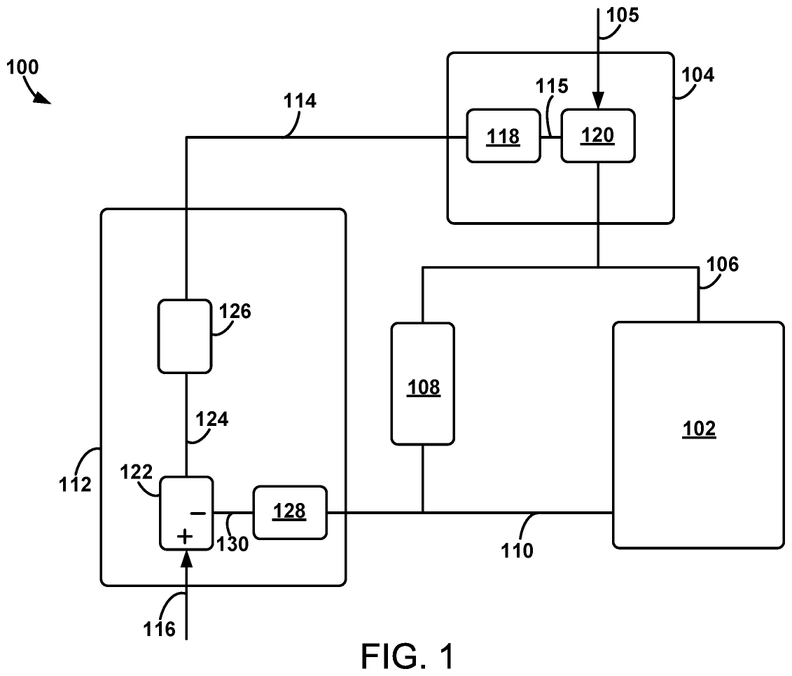

FIG. 1 is a schematic diagram of a control circuit 100. The control circuit 100 includes a digital load 102, a voltage conversion circuit 104 configured to provide a supply voltage 106 to the digital load 102, an oscillator 108 configured to provide, to the digital load 102, a clock signal 110 having an oscillation frequency that (i) is (e.g., monotonically) dependent on the supply voltage 106 and (ii) is less than a reciprocal of a critical path delay of the digital load 102, and a phase detector 112 configured to provide, to the voltage conversion circuit 104, a phase signal 114 that is indicative of a phase difference between the clock signal 110 and a reference signal 116. The voltage conversion circuit 104 is further configured to adjust the supply voltage 106 based on the phase signal 114 such that the oscillator 108 changes the oscillation frequency to reduce the phase difference.

The digital load 102 can take the form of a microprocessor, a graphics processing unit (GPU), or any digital circuit or system that includes combinational or sequential synchronous logic circuits. The digital load 102 is connected to receive the supply voltage 106 and the clock signal 110.

The voltage conversion circuit 104 includes a loop filter 118 (e.g., a low pass filter) configured to receive and filter the phase signal 114. The loop filter 118 can be implemented as a special-purpose (e.g., CMOS) integrated circuit, for example. The loop filter 118 can include any circuit configured to maintain the stability of the control circuit 100, i.e., to help prevent the occurrence of positive feedback loops that can cause failures of the control circuit 100.

The voltage conversion circuit 104 also includes a voltage converter 120 configured to receive the (filtered) phase signal 115 from the loop filter 118. The voltage converter 120 is configured to adjust the supply voltage 106 based on the phase signal 115 that has been filtered by the loop filter 118, as described in more detail below. The voltage converter 120 can take the form of a buck converter, a switched capacitor converter, or a linear regulator, among other forms. The voltage conversion circuit 104 (e.g., the voltage converter 120) is powered by an input voltage 105 which is typically greater than the supply voltage 106.

The oscillator 108 can take the form of any circuit configured to generate the clock signal 110 (e.g., a square wave) having an oscillation frequency that is dependent on the supply voltage 106. The oscillator 108 can take the form of a voltage controlled oscillator (VCO), for example. The oscillator 108 provides the clock signal 110 to the digital load 102 and to the phase detector 112. Generally, the oscillation frequency of the clock signal 110 will be (e.g., monotonically) dependent on the supply voltage 106. That is, as the supply voltage 106 increases the oscillation frequency of the clock signal 110 increases, and as the supply voltage 106 decreases the oscillation frequency of the clock signal 110 decreases. As shown in FIG. 1, the oscillator 108 receives the supply voltage 106 as an input and provides the clock signal 110 as an output.

The oscillator 108 is structured such that, for a given supply voltage 106, the oscillation frequency of the clock signal 110 is (e.g., slightly) less than a reciprocal of a critical path delay of the digital load 102. For example, the period of the clock signal 110 could be anywhere from 100.1% to 105% of the critical path delay of the digital load 102. Changes in the supply voltage 106 affect the oscillation frequency of the clock signal 110 and the critical path delay of the digital load 102 in a similar manner. As such, the control circuit 100 inherently avoids timing errors.

The phase detector 112 includes a frequency divider 128, a subtractor circuit 122, and a time-to-digital converter 126. The frequency divider 128 is a circuit configured, as known in the art, to generate an output signal with the input signal having a frequency that is an integer multiple of the frequency of the output signal. The frequency divider 128 receives the clock signal 110 from the oscillator 108 and provides a downscaled clock signal 130 to the subtractor circuit 122. In some examples, the frequency of the reference signal 116 is orders of magnitude less than the target frequency of the clock signal 110. Thus, the frequency divider 128 is used so that the reference signal 116 is still a useful basis for comparison to the clock signal 110.

The subtractor circuit 122 can take the form of an XOR gate or an XNOR gate, among other possibilities. Any circuit configured to generate a signal indicating a binary difference between the downscaled clock signal 130 (or the clock signal 110) and the reference signal 116 can be used as well. The subtractor circuit 122 generates a difference signal 124 that indicates a difference between the reference signal 116 and the downscaled clock signal 130 (or the clock signal 110). In the binary context, this means that the difference signal 124 indicates whether the reference signal 116 and the downscaled clock signal 130 (or the clock signal 110) are equal or not. A detected inequality between the reference signal 116 and the downscaled clock signal 130 (or the clock signal 110) indicates a nonzero phase difference because the rising or falling edges of the signals do not coincide.

The time-to-digital converter 126 is a circuit configured to receive the difference signal 124 and determine a duration of time during which the difference between the reference signal 116 and the downscaled clock signal 130 (or the clock signal 110) is non-zero. The longer that the difference is non-zero, the larger the phase difference is between the reference signal 116 and the downscaled clock signal 130 (or the clock signal 110). Thus, the phase detector 112 (e.g., the time-to-digital converter 126) generates the phase signal 114 that is indicative of a degree and a polarity of the phase difference between the reference signal 116 and the downscaled clock signal 130 (or the clock signal 110).

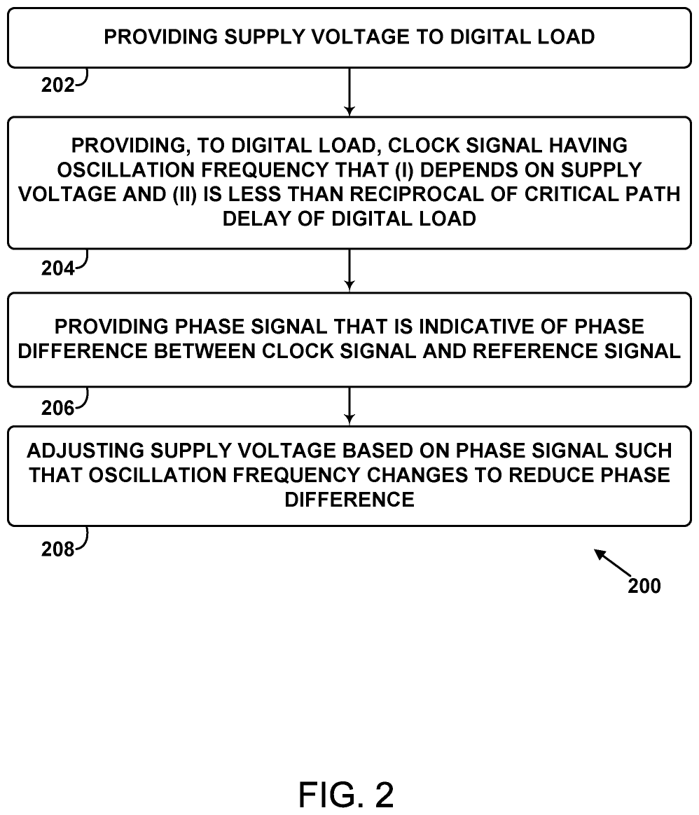

FIG. 2 is a block diagram of a method 200. The method 200 can be performed by the control circuit 100, for example.

At block 202, the method 200 includes providing a supply voltage to a digital load. For example, the voltage conversion circuit 104 can provide the supply voltage 106 to the digital load 102 (e.g., to power the digital load 102). The voltage conversion circuit 104 can also provide the supply voltage 106 to the oscillator 108.

At block 204, the method 200 includes providing, to the digital load, a clock signal having an oscillation frequency that (i) is (e.g., monotonically) dependent on the supply voltage and (ii) is less than a reciprocal of a critical path delay of the digital load. For example, the oscillator 108 can provide the clock signal 110 (e.g., a square wave) to the digital load 102. The clock signal 110 has an oscillation frequency that (i) is (e.g., monotonically) dependent on the supply voltage 106 and (ii) is less than a reciprocal of a critical path delay of the digital load 102. That is, the period of the clock signal 110 is greater than the critical path delay of the digital load 102. For example, the period of the clock signal 110 could be anywhere from 100.1% to 105% of the critical path delay of the digital load 102. The control circuit 100 is wired such that changes in the supply voltage 106 affect the oscillation frequency of the clock signal 110 and the critical path delay of the digital load 102 in a similar manner. As such, the control circuit 100 inherently avoids timing errors.

At block 206, the method 200 includes providing a phase signal that is indicative of a phase difference between the clock signal and a reference signal. For example, the phase detector 112 can provide the phase signal 114 that is indicative of a phase difference between the clock signal 110 (and/or the downscaled clock signal 130) and a reference signal 116. As noted above, the phase signal 114 can represent or indicate a duration of time during which the clock signal 110 (or the downscaled clock signal 130) and the reference signal 116 are unequal. For example, a voltage of the phase signal 114 can monotonically increase with respect to the time during which the clock signal 110 (or the downscaled clock signal 130) and the reference signal 116 are unequal. Thus, the voltage magnitude of the phase signal 114 can indicate the magnitude of the phase difference between the clock signal 110 (and/or the downscaled clock signal 130) and the reference signal 116. The polarity of the phase signal 114 can indicate whether the clock signal 110 (or the downscaled clock signal 130) lags or leads the reference signal 116.

More specifically, the subtractor circuit 122 can generate a difference signal 124 indicating a difference between the reference signal 116 and the clock signal 110 (or the downscaled clock signal 130). The time-to-digital converter 126 can determine the duration of time during which the difference between the reference signal 116 and the clock signal 110 (or the downscaled clock signal 130) is non-zero, and accordingly generate the phase signal 114. As such, in various embodiments, the phase detector 112 (e.g., the subtractor circuit 122) can receive either the clock signal 110 or the downscaled clock signal 130 that is generated by the frequency divider 128.

At block 208, the method 200 includes adjusting the supply voltage based on the phase signal such that the oscillation frequency changes to reduce the phase difference. For example, the voltage conversion circuit 104 can adjust the supply voltage 106 based on the phase signal 114 such that the oscillation frequency of the clock signal 110 changes to reduce the phase difference between the clock signal 110 and the reference signal 116.

In some examples, the loop filter 118 receives the phase signal 114 from the phase detector 112 and filters (e.g., low pass filters) the phase signal 114 to generate the filtered phase signal 115. In this context, the voltage conversion circuit 104 adjusts the supply voltage 106 based on the phase signal 115 that has been filtered.

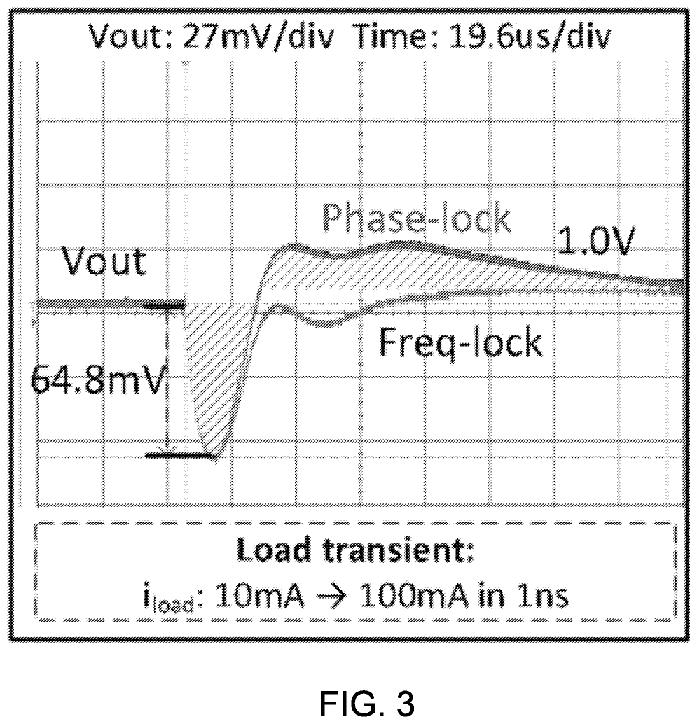

FIG. 3 illustrates an embodiment in which the supply voltage 106 experiences a droop (decrease) of about 64.8 millivolts (mV) relative to a steady state supply voltage of 1.0 V. This could be caused by an increase in current demand to the digital load 102, from 10 milliamps (mA) to 100 mA over 1 nanosecond (ns), for example. In some embodiments, the phase detector 112 provides the phase signal 114 such that the phase signal 114 indicates that the clock signal 110 is lagging behind the reference signal 116 by a first lag time (or a first phase difference). The lag of the clock signal 110 behind the reference signal 116 could be induced by the voltage droop illustrated in FIG. 3, for example. As shown by the curve marked “Phase-lock” in FIG. 3, the voltage conversion circuit 104 can adjust the supply voltage 106 such that the oscillation frequency of the clock signal 110 is increased to be greater than an oscillation frequency of the reference signal 116 for a duration of time so that the clock signal 110 thereafter lags the reference signal 116 by a second lag time (or a second phase difference) that is less than the first lag time (or first phase difference). That is, the voltage conversion circuit 104 adjusts the supply voltage 106 such that the clock signal 110 not only regains frequency lock with the reference signal 116, but such that the clock signal 110 running at the oscillation frequency that is greater than the oscillation frequency of the reference signal 116 causes the clock signal 110 to “catch up” with and attain true phase lock with the reference signal 116. That is, the control circuit 100 can control the clock signal 110 such that the lag time or phase difference between the clock signal 110 and the reference signal 116 is reduced to be substantially equal to zero. Thus, in this example, the supply voltage 106 is controlled such that the oscillation frequency of the clock signal 110 changes from being less than to being greater than the oscillation frequency of the reference signal 116. Thereafter, the oscillation frequency of the clock signal 110 is controlled to asymptotically decrease to be substantially equal to the oscillation frequency of the reference signal 116.

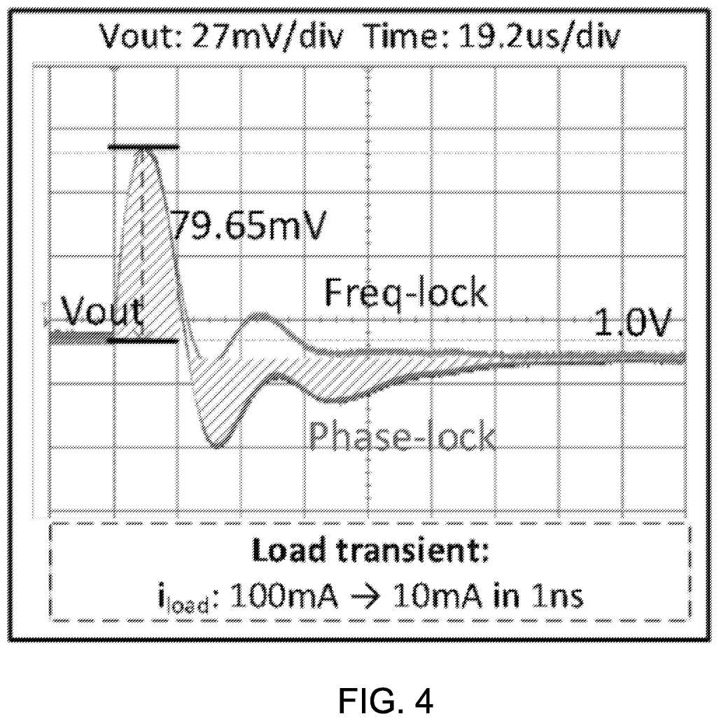

FIG. 4 illustrates an embodiment in which the supply voltage 106 experiences a spike (increase) of about 79.65 mV relative to a steady state supply voltage of 1.0 V. This could be caused by a decrease in current demand to the digital load 102, from 100 mA to 10 mA over 1 ns, for example. In some embodiments, the phase detector 112 provides the phase signal 114 such that the phase signal 114 indicates that the clock signal 110 is leading the reference signal 116 by a first lead time (or a first phase difference). The lead time of the clock signal 110 ahead of the reference signal 116 could be induced by the voltage spike illustrated in FIG. 4, for example. As shown by the curve marked “Phase-lock” in FIG. 4, the voltage conversion circuit 104 can adjust the supply voltage 106 such that the oscillation frequency of the clock signal 110 is decreased to be less than an oscillation frequency of the reference signal 116 for a duration of time so that the clock signal 110 thereafter leads the reference signal 116 by a second lead time (or a second phase difference) that is less than the first lead time (or first phase difference). That is, the voltage conversion circuit 104 adjusts the supply voltage 106 such that the clock signal 110 not only regains frequency lock with the reference signal 116, but such that the clock signal 110 running at the oscillation frequency that is less than the oscillation frequency of the reference signal 116 causes the reference signal 116 to “catch up” with and attain true phase lock with the clock signal 110. That is, the control circuit 100 can control the clock signal 110 such that the lead time or phase difference between the clock signal 110 and the reference signal 116 is reduced to be substantially equal to zero. Thus, in this example, the supply voltage 106 is controlled such that the oscillation frequency of the clock signal 110 changes from being greater than to being less than the oscillation frequency of the reference signal 116. Thereafter, the oscillation frequency of the clock signal 110 is controlled to asymptotically increase to be substantially equal to the oscillation frequency of the reference signal 116.

While various example aspects and example embodiments have been disclosed herein, other aspects and embodiments will be apparent to those skilled in the art. The various example aspects and example embodiments disclosed herein are for purposes of illustration and are not intended to be limiting, with the true scope and spirit being indicated by the following claims.

What is claimed is:

1. A control circuit comprising:
a digital load;
a voltage conversion circuit configured to provide a supply voltage to the digital load;
an oscillator configured to provide, to the digital load, a clock signal having an oscillation frequency that (i) depends on the supply voltage and (ii) is less than a reciprocal of a critical path delay of the digital load; and
a phase detector configured to provide, to the voltage conversion circuit, a phase signal that is indicative of a phase difference between the clock signal and a reference signal,
wherein the voltage conversion circuit is further configured to adjust the supply voltage based on the phase signal such that the oscillator changes the oscillation frequency to reduce the phase difference.

2. The control circuit of claim 1, wherein the voltage conversion circuit comprises:
a loop filter configured to filter the phase signal; and
a voltage converter configured to adjust the supply voltage based on the phase signal that has been filtered by the loop filter.

3. The control circuit of claim 2, wherein the loop filter comprises a low pass filter.

4. The control circuit of claim 2, wherein the voltage converter comprises a buck converter, a switched capacitor converter, or a linear regulator.

5. The control circuit of claim 1, wherein the phase detector comprises:
a subtractor circuit configured to generate a difference signal indicating a difference between the reference signal and the clock signal; and
a time-to-digital converter configured to determine a duration of time during which the difference is non-zero.

6. The control circuit of claim 5, wherein the phase detector further comprises a frequency divider that is configured to receive the clock signal and generate a downscaled clock signal, wherein the subtractor circuit is configured to receive the downscaled clock signal.

7. The control circuit of claim 1, wherein the digital load comprises a microprocessor or a graphics processing unit.

8. The control circuit of claim 1, wherein
the phase detector is configured to provide the phase signal such that the phase signal indicates that the clock signal is lagging the reference signal by a first lag time, and
the voltage conversion circuit is configured to adjust the supply voltage such that the oscillation frequency of the clock signal is greater than an oscillation frequency of the reference signal for a duration of time so that the clock signal thereafter lags the reference signal by a second lag time that is less than the first lag time.

9. The control circuit of claim 8, wherein the second lag time is substantially equal to zero.

10. The control circuit of claim 1, wherein
the phase detector is configured to provide the phase signal such that the phase signal indicates that the clock signal is leading the reference signal by a first lead time, and
the voltage conversion circuit is configured to adjust the supply voltage such that the oscillation frequency of the clock signal is less than an oscillation frequency of the reference signal for a duration of time so that the clock signal thereafter leads the reference signal by a second lead time that is less than the first lead time.

11. The control circuit of claim 10, wherein the second lead time is substantially equal to zero.

12. A method comprising:
providing a supply voltage to a digital load;
providing, to the digital load, a clock signal having an oscillation frequency that (i) depends on the supply voltage and (ii) is less than a reciprocal of a critical path delay of the digital load;
providing a phase signal that is indicative of a phase difference between the clock signal and a reference signal; and
adjusting the supply voltage based on the phase signal such that the oscillation frequency changes to reduce the phase difference.

13. The method of claim 12, further comprising:
filtering the phase signal,
wherein adjusting the supply voltage based on the phase signal comprises adjusting the supply voltage based on the phase signal that has been filtered.

14. The method of claim 13, wherein filtering the phase signal comprises performing a low-pass filter operation.

15. The method of claim 12, further comprising:
generating a difference signal indicating a difference between the reference signal and the clock signal; and
determining a duration of time during which the difference is non-zero.

16. The method of claim 15, further comprising generating a downscaled clock signal, wherein the difference signal indicates a difference between the reference signal and the downscaled clock signal.

17. The method of claim 12, wherein
providing the phase signal comprises providing the phase signal such that the phase signal indicates that the clock signal is lagging the reference signal by a first lag time, and
adjusting the supply voltage comprises adjusting the supply voltage such that the oscillation frequency of the clock signal is greater than an oscillation frequency of the reference signal for a duration of time so that the clock signal thereafter lags the reference signal by a second lag time that is less than the first lag time.

18. The method of claim 17, wherein the second lag time is substantially equal to zero.

19. The method of claim 12, wherein
providing the phase signal comprises providing the phase signal such that the phase signal indicates that the clock signal is leading the reference signal by a first lead time, and
adjusting the supply voltage comprises adjusting the supply voltage such that the oscillation frequency of the clock signal is less than an oscillation frequency of the reference signal for a duration of time so that the clock signal thereafter leads the reference signal by a second lead time that is less than the first lead time.

20. The method of claim 19, wherein the second lead time is substantially equal to zero.
